(19) United States
(12) Patent Application Publication
(10) Pub. No.: US 2026/0114163 A1
(43) Pub. Date: Apr. 23, 2026

(54) LENS ARRAY STRUCTURE, METHOD OF FABRICATING THE SAME, DISPLAY DEVICE INCLUDING THE SAME AND ELECTRONIC DEVICE INCLUDING THE SAME

(71) Applicant: Samsung Display Co., Ltd., Yongin-Si (KR)

(72) Inventor: Jong Jang PARK, Yongin-si (KR)

(21) Appl. No.: 19/214,039

(22) Filed: May 21, 2025

(30) Foreign Application Priority Data
Oct. 22, 2024 (KR) 10-2024-0145103

(51) Int. Cl. H10K 59/80; G02B 3/00

(52) U.S. Cl. CPC H10K 59/879; G02B 3/0037

(57) ABSTRACT

A display device includes a display panel, and a lens array structure on the display panel. The lens array structure includes a lens having a higher refractive index at an outer portion than at a central portion. In a method of fabricating a lens array structure, a preliminary lens is formed by coating a resin material on a base layer. A vacuum ultraviolet (VUV) light is irradiated through an outermost surface of the preliminary lens to form a lens having a higher refractive index at an outer portion than at a center.

### CROSS-REFERENCE TO RELATED APPLICATION AND CLAIM OF PRIORITY

This application claims priority to Korean Patent Application No. 10-2024-0145103 filed on Oct. 22, 2024 in the Korean Intellectual Property Office (KIPO), the entire disclosure of which is incorporated by reference herein.

### TECHNICAL FIELD

Embodiments of this patent application relate to a lens array structure, a method of fabricating the same, a display device including the same, and an electronic device including the same.

### BACKGROUND

In display devices such as organic light emitting diode (OLED) display devices and liquid crystal display (LCD) devices, a display substrate including thin film transistors (TFT) and various wirings is provided. A display structure including electrodes and an emission layer may be formed on the display substrate.

The display device includes a plurality of pixels, and light may be emitted from each pixel. When light emitted from a pixel is dispersed by reflection, scattering, or the like, condensing efficiency is reduced and overall luminance and light efficiency of the display device may be lowered.

### SUMMARY

According to an aspect of the present disclosure, there is provided a lens array structure having improved optical properties and optical efficiency.

According to an aspect of the present disclosure, there is provided a method of fabricating a lens array structure having improved optical properties and optical efficiency.

According to an aspect of the present disclosure, there is provided a display device having improved optical properties and optical efficiency.

According to an aspect of the present disclosure, there is provided an electronic device including the lens array structure or the display device.

A display device may include a display panel, and a lens array structure on the display panel. The lens array structure may include a lens having a higher refractive index at an outer portion than at a central portion.

In some embodiments, the lens may have a refractive index gradient that increases in a direction from a center to an outermost surface.

In some embodiments, the lens may have a stepwise refractive index gradient.

In some embodiments, the lens may include an intermediate portion between the central portion and the outer portion, and a refractive index of the intermediate portion may be greater than that of the central portion and less than that of the outer portion.

In some embodiments, the intermediate portion may include a first intermediate portion and a second intermediate portion sequentially formed from the central portion, and a refractive index of the first intermediate portion may be less than that of the second intermediate portion.

In some embodiments, the lens may have a continuous refractive index gradient from the center.

In some embodiments, the display panel may include a plurality of light-emitting devices, and each lens of the lens array structure may be aligned with a corresponding light-emitting device in the plurality of light-emitting devices.

In some embodiments, the display panel may further include an encapsulating layer covering the light-emitting devices, and the lens array structure may be disposed on the encapsulating layer.

In some embodiments, the lens array structure may have a single-layered lens layer.

In some embodiments, the lens may include a resin material including a silicon-hydrogen (Si—H) bond or a nitrogen-hydrogen (N—H) bond.

In some embodiments, the lens may include a siloxane-based resin or a silazane-based resin.

An electronic device includes the above-described display device, a memory, and a processor for executing instructions included in the memory to control an operation of the display device.

A lens array structure includes a base layer, and a lens array structure including a lens array layer disposed on the base layer and having a higher refractive index at the outer portion than at the center.

In some embodiments, the lens may have a refractive index gradient that increases stepwise or continuously in a direction from the center toward the outermost surface.

In some embodiments, the lens may include poly(methylhydrosiloxane) (PMHS) or perhydropolysilazane (PHPS).

In a method for fabricating a lens array structure, a preliminary lens may be formed by coating a resin material on a base layer. Vacuum ultraviolet (VUV) light may be irradiated through an outermost surface of the preliminary lens to form a lens having a higher refractive index at an outer portion than at a center.

In some embodiments, the resin material may include a silicon-hydrogen (Si—H) bond or a nitrogen-hydrogen (N—H) bond. In irradiating the preliminary lens with the vacuum ultraviolet light, the Si—H bond or the N—H bond may be decomposed at a region of the preliminary lens region through which the ultraviolet light is transmitted.

In some embodiments, in irradiating the outermost surface of the preliminary lens with the vacuum ultraviolet light, a refractive index gradient that decreases in a direction from the outermost surface of the preliminary lens to a center of the preliminary lens may be formed.

In some embodiments, in irradiating the outermost surface of the preliminary lens with vacuum ultraviolet light, a vacuum ultraviolet light source may be rotated along the outermost surface of the preliminary lens.

In some embodiments, in irradiating the outermost surface of the preliminary lens with vacuum ultraviolet light, the vacuum ultraviolet light source may be moved in a spiral trajectory from a peak point of the preliminary lens.

According to embodiments of the present disclosure, a lens included in a lens array structure may have a structure in which the refractive index of the lens material increases in a direction from a central portion to an outer surface thereof. Accordingly, the lens array structure may be disposed on a display panel to increase a extraction efficiency of light emitted from each pixel.

According to embodiments, a refractive index of an outer surface portion of the lens may be increased compared to that of the central portion by a curing process using vacuum UV (VUV) light, and uniformity of the refractive index in an area corresponding to the same radius may be improved using a spiral curing.

### BRIEF DESCRIPTION OF THE DRAWINGS

FIG. 1 is a schematic perspective view illustrating a lens array structure according to embodiments.

FIGS. 2 and 3 are cross-sectional views of a lens included in a lens array structure according to some embodiments.

FIG. 4 is a graph showing a refractive index distribution of a lens included in a lens array structure and a cross-sectional view of the lens according to some embodiments.

FIG. 5 is a schematic perspective view illustrating a display device according to embodiments.

FIG. 6 is a schematic plan view illustrating a display device according to embodiments.

FIG. 7 is a schematic cross-sectional view illustrating a display device according to embodiments.

FIGS. 8 and 9 are schematic cross-sectional views illustrating a method of fabricating a lens array structure according to embodiments.

FIGS. 10 and 11 are a cross-sectional view and a plan view, respectively, for describing a light irradiation process of a lens included in a lens array structure.

FIG. 12 is a block diagram of an electronic device in accordance with aspects of the present disclosure.

FIG. 13 is a schematic diagram of an electronic device in accordance with various embodiments.

### DETAILED DESCRIPTION OF THE EMBODIMENTS

Hereinafter, embodiments of the present disclosure will be described in more detail with reference to the attached drawings. The same reference numerals can be used for indicating the same elements in the drawings, and repeated descriptions of the same elements can be omitted. Embodiments disclosed in the attached drawings are provided for example, and are to be understood to include all modifications, equivalents and substitutes included in the spirit and technical scope of the present disclosure.

The terms “on”, “connected”, “coupled,” etc., used herein refers to a direct placement/connection/combination, and also refers to a case where another element is interposed between two different elements.

The terms such as “first”, “second”, “below”, “below”, “above,” “above,” etc., are used in a relative sense to distinguish different elements or positions, and do not specify an absolute position or an absolute order.

In the accompanying drawings, a first direction and a second direction may refer to two directions parallel to a display surface of a display device DD or a top surface of a base layer 50. For example, the first direction and the second direction may be orthogonal to each other. For example, the first direction may correspond to an X-direction (a row direction), and the second direction may correspond to a Y-direction (a column direction). A third direction may be perpendicular to the first direction and the second direction. The third direction may correspond to a Z-direction (a thickness direction) of the display device DD or a lens array structure LA.

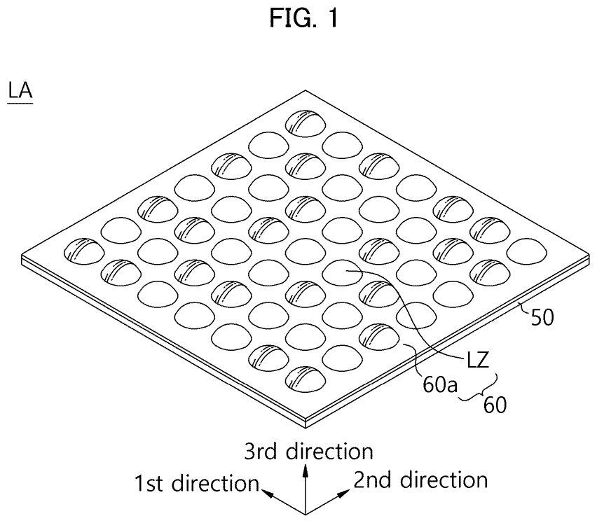

FIG. 1 is a schematic perspective view illustrating a lens array structure according to embodiments.

Referring to FIG. 1, the lens array structure LA may include the base layer 50 and a lens array layer 60 formed on the top surface of the base layer 50.

The base layer 50 may include a transparent resin film. For example, the base layer 50 may include a transparent resin material such as polyethylene terephthalate (PET), polycarbonate (PC), polyethylene (PE), polypropylene (PP), polysulfone (PSF), polymethyl methacrylate (PMMA), triacetylcellulose (TAC), cycloolefin polymer (COP), cycloolefin copolymer (COC), or the like. In some embodiments, the base layer 50 may include a transparent inorganic film such as a glass film.

The lens array layer 60 may include a plurality of lenses LZ. The plurality of lenses LZ may be arranged along the first direction to form a lens row. A plurality of the lens rows may be arranged along the second direction to form a lens array.

The lens array layer 60 may include a photo-sensitive resin material. According to some embodiments, the lens array layer 60 may include a resin material containing silicon atoms.

In some embodiments, the lens array layer 60 may include a resin material containing a silicon-hydrogen (Si—H) bond and/or a nitrogen-hydrogen (N—H) bond. The lens array layer 60 may include a siloxane-based resin and/or a silazane-based resin. In some implementations, the lens array layer 60 may include a silazane-based resin.

In some embodiments, the lens array layer 60 may include poly(methylhydrosiloxane) (PMHS). In yet other embodiments, the lens array layer 60 may include perhydropolysilazane (PHPS).

The lens LZ may include a portion of a sphere. For example and without limitation, the lens LZ may have a hemispherical shape.

As illustrated in FIG. 1, the lenses LZ may be physically spaced apart from each other. Lower portions of adjacent lenses LZ may be merged with each other to create an integrally connected array of lenses.

In some embodiments, the separate independent base layer 50 may be omitted. For example and without limitation, the lens array layer 60 includes a support portion 60a on which the lenses LZ are arranged, the support portion 60a may serve as the base layer, and the lenses LZ may protrude from the support portion 60a while being integrally formed with the support portion 60a.

The lens LZ may have a non-uniform refractive index distribution. According to embodiments, an outer portion including an outermost surface of the lens LZ may have a refractive index greater than that of a central portion including a center of the lens LZ (as used herein a center of the lens refers to a center of a bottom surface at which the lens LZ meets the support portion 60a). In some implementations, a refractive index of the lens LZ may have a refractive index distribution that increases in a direction from the center of the lens to the outermost surface of the lens.

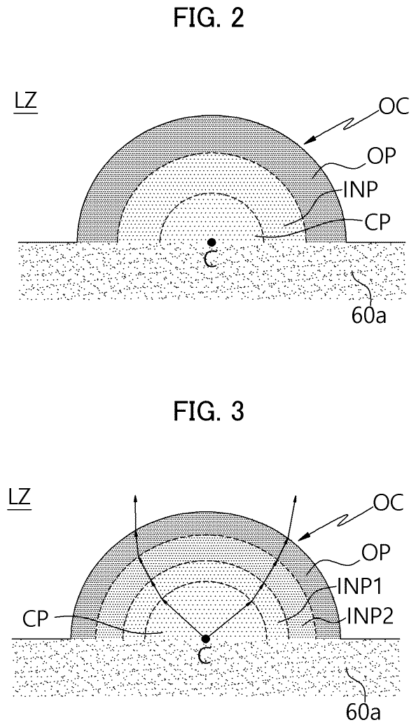

FIGS. 2 and 3 are cross-sectional views of a lens included in a lens array structure according to some embodiments.

Referring to FIG. 2, the lens LZ may include an outer portion OP and a central portion CP. The outer portion OP may include an outermost surface OC corresponding to a curved surface of the lens LZ. The outer portion OP may include a portion of lens material having a predetermined thickness in a direction (e.g., a radial direction of the lens LZ) from the outermost surface OC to the center C of the lens LZ. For example, the outer portion OP may include a region within 1/10, ⅛, ⅕, ⅓, or ½ of the radius of the lens LZ from the outermost surface OC in the radial direction.

The central portion CP may include a region of lens material within 1/10, ⅛, ⅕, ⅓, or ½ of the radius of the lens LZ in a direction from the center C of the lens LZ to the outermost surface OC.

A refractive index of the outer portion OP may be greater than a refractive index of the central portion CP. In some embodiments, an average refractive index of the outer portion OP may be greater than an average refractive index of the central portion CP. For example and without limitation, an average of refractive indices at the outermost surface OC and an inner surface (indicated by a dotted line) of the outer portion OP may be greater than an average of refractive indices at a center C and an outer surface (indicated by a dotted line) of the central portion CP.

In another non-limiting example, the refractive index of the outer portion OP may be in a range from about 1.6 to about 1.8, or from about 1.65 to about 1.8. The refractive index of the central portion CP may be about 1.4 or more and less than about 1.6, from about 1.45 to about 1.58, or from about 1.5 to about 1.57.

In some embodiments, the lens LZ may further include an intermediate portion INP located between the central portion CP and the outer portion OP. The intermediate portion INP may serve as a buffer region for reducing a gap in a refractive index difference between the central portion CP and the outer portion OP. The intermediate portion INP may refer to a region that excludes the central portion CP and the outer portion OP.

A refractive index of the intermediate portion INP may be greater than the refractive index of the central portion CP and less than the refractive index of the outer portion OP. For example and without limitation, an average of refractive indices at an outer surface (e.g., an interface between the outer portion OP and the intermediate portion INP as indicated by a dotted line) and an inner surface (e.g., an interface between the central portion CP and the intermediate portion INP as indicated by a dotted line) of the intermediate portion INP may be less than the above-described average refractive index of the outer portion OP and may be greater than the above described average refractive index of the central portion CP.

In a non-limiting example, the refractive index of the intermediate part INP may be in a range from about 1.5 to about 1.7, from about 1.55 to about 1.65, or from about 1.6 to about 1.65.

Referring to FIG. 3, an inside of the lens LZ may be additionally divided according to a change or a distribution of a refractive index.

According to an embodiment illustrated in FIG. 3, the intermediate portion INP may include a first intermediate portion INP1 and a second intermediate portion INP2 having different refractive indices. In some implementations, the first intermediate portion INP1, the second intermediate portion INP2 and the outer portion OP may be sequentially formed from the central portion CP.

The second intermediate portion INP2 may have a refractive index greater than that of the first intermediate portion INP1. For example, an average of refractive indices at an outer surface (e.g., an interface between the outer portion OP and the second intermediate portion INP2 as indicated by a dotted line) and an inner surface (e.g., an interface between the first intermediate portion INP1 and the second intermediate portion INP2 as indicated by a dotted line) of the second intermediate portion INP2 may be greater than an average of refractive indices at an outer surface (e.g., an interface between the first intermediate portion INP1 and the second intermediate portion INP2 indicated by a dotted line) and an inner surface (e.g., an interface between the first intermediate portion INP1 and the central portion CP as indicated by a dotted line) of the first intermediate portion INP2.

According to embodiments, the refractive index may increase in an order of the central portion CP, the first intermediate portion INP1, the second intermediate portion INP2 and the outer portion OP.

For example, as indicated by an arrow in FIG. 3, diffuse light entering at center C may be refracted with a smaller angle of refraction than the angle incidence at an interface of each region while passing through the first intermediate portion INP1, the second intermediary portion INP2 and the outer portion OP where the refractive index may sequentially increase. Thus, light extraction efficiency may be increased while reducing the amount of light scattered through each lens LZ as light is directed out towards a top of the lens.

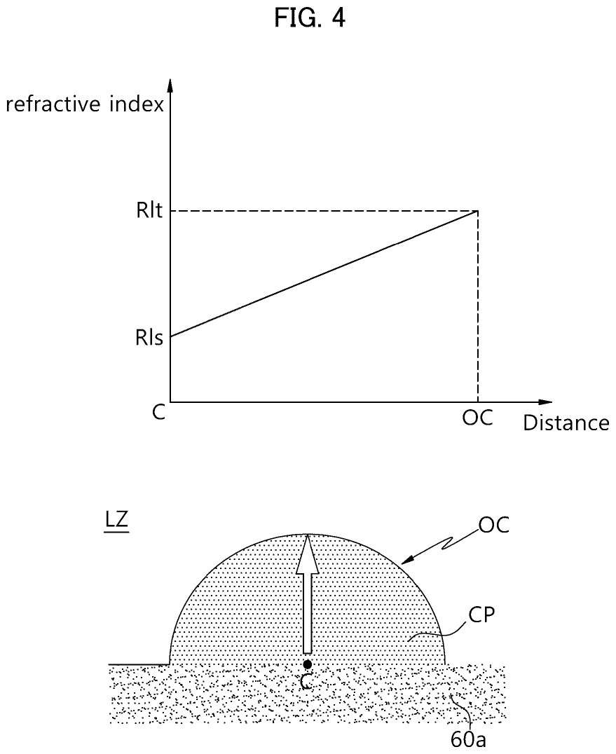

FIG. 4 is a graph showing a refractive index distribution of a lens included in a lens array structure and a cross-sectional view of the lens according to some embodiments.

Referring to FIG. 4, the lens LZ may include a refractive index gradient. According to embodiments, the refractive index may increase gradually or continuously from the center C to the outermost surface OC in the lens LZ, as illustrated in the graph of FIG. 4.

For example, the lens LZ may have a first refractive index RIs at the center C, and may have a second refractive index RIt greater than the first refractive index RIs at the outermost surface OC. The refractive index of the lens LZ may gradually and continuously increase from the first refractive index RIs to the second refractive index RIt along an arrow direction indicated in a cross-section of the lens LZ of FIG. 4.

In some embodiments, the refractive index may increase in a straight line shape as indicated in the graph of FIG. 4. In an embodiment, the refractive index may increase in a curved shape. In some embodiments, the refractive index may increase in a concave or convex curved shape with respect to the straight line of the graph of FIG. 4.

As described above, the lens LZ may have a structure in which a refractive index increases continuously or stepwise from the center C toward the outermost surface OC. The shapes of the regions of the lens LZ shown in FIGS. 2 and 3 are exemplary and may be appropriately modified according to a change in light irradiation conditions as will be described below. For example, the intermediate INP may be omitted or may be divided into three or more sub-intermediate portions.

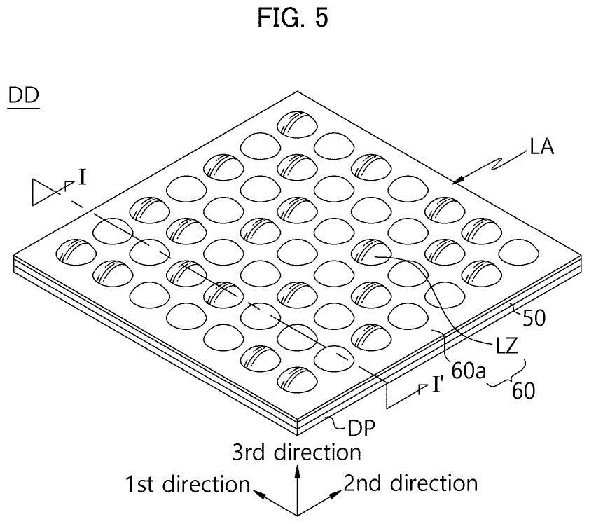

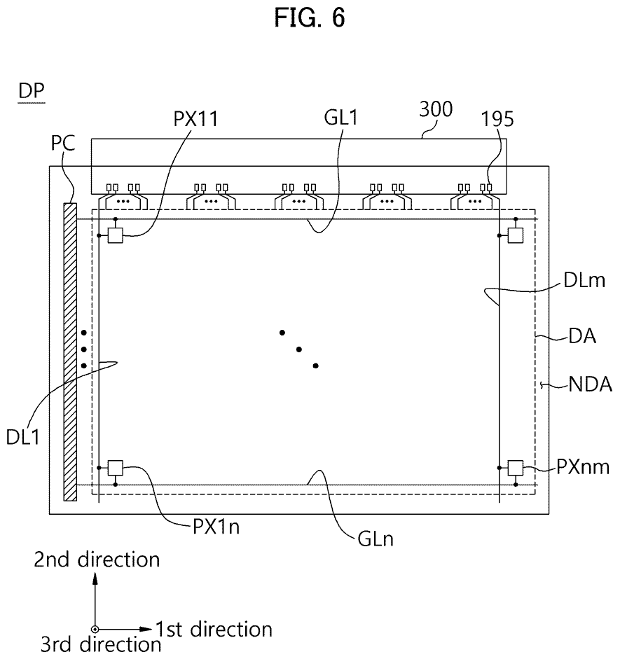

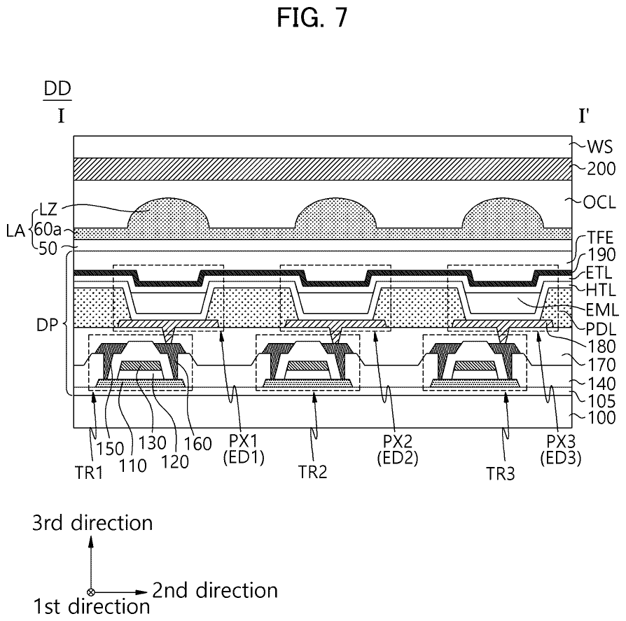

FIG. 5 is a schematic perspective view illustrating a display device according to embodiments. FIG. 6 is a schematic plan view illustrating a display device according to embodiments. FIG. 7 is a schematic cross-sectional view illustrating a display device according to embodiments.

Specifically, FIG. 6 is a plan view for describing arrangement of pixels included in a display panel DP. FIG. 7 is a cross-sectional view taken along line I-I′ of FIG. 5 in a thickness direction.

Referring to FIG. 5, the display device DD may include the display panel DP and the lens array structure LA, described with reference to FIGS. 1 to 4, disposed on the display panel DP.

Referring to FIG. 6, the display panel DP may include a display area DA and a non-display area NDA. The display area DA of the display panel DP may provide a surface on which an image may be displayed and a user's touch/command may be input. The non-display area NDA may correspond to a peripheral area or a bezel area of the display device DD.

A plurality of pixels PX11 to PXnm may be arranged in the display area DA of the display panel DP.

In example embodiments, a pixel circuit including scan lines (gate lines) GL1 to GLn forming first to n^{th} rows and data lines DL1 to DLm forming first to m^{th} columns may be arranged on a base substrate 100 (see FIG. 7) of the display device DD or the display panel DP. Each of the pixels PX11 to PXnm may be connected to a corresponding n^{th} row scan line among a plurality of scan lines GL1 to GLn and a corresponding m^{th} column data line among a plurality of data lines DL1 to DLm.

Each of the pixels PX11 to PXnm may further include a pixel driving circuit including a transistor and a light-emitting device as will be described below. Although not illustrated in detail in FIG. 6, the pixel circuit may further include wirings such as a power line, a ground line, etc.

FIG. 6 illustrates that the data lines DL1 to DLm extend in the second direction and the scan lines GL1 to GLn extend in the first direction, but the construction of the data lines and the scan lines is not limited to that illustrated in FIG. 6.

A peripheral circuit PC may be disposed in the peripheral area of the display device DD or the non-display area NDA of the display panel DP. For example, the peripheral circuit PC may include a gate driving circuit. The gate driving circuit may be integrated into the display panel DP by an oxide silicon gate (OSG) driver circuit, an amorphous silicon gate (ASG) driver circuit, or a polysilicon gate (PSG) driver circuit.

The display device DD may further include a printed circuit board 300. Pads 195 of the pixel circuit may be disposed at one end portion of the non-display area NDA. The printed circuit board 300 may be electrically connected to the pixel circuit through the pads 195. For example, the printed circuit board 300 may be electrically connected to the pads 195 by a heating-compression process using a conductive intermediate structure such as an anisotropic conductive film (ACF).

An integrated circuit (IC) such as a data driving circuit may be disposed on the printed circuit board 300. In some embodiments, an integrated circuit (IC) chip in the form of a chip-on-film (COF) may be mounted on the printed circuit board 300.

Referring to FIG. 7, the display panel DP may include a base substrate 100, a circuit layer including transistors TR1, TR2, and TR3 stacked on the base substrate 100, and light-emitting devices ED1, ED2 and ED3 disposed on the circuit layer.

The base substrate 100 may serve as a supporting substrate or as a back-plane substrate of an image display device. The base substrate 100 may be a glass substrate or a plastic substrate.

In some embodiments, the base substrate 100 may include a polymer material having transparent and flexible properties. In this case, the base substrate 100 may be applied in a transparent flexible display device. For example and without limitation, the base substrate 100 may include a polymer material such as polyimide, polysiloxane, an epoxy resin, an acrylic resin, polyester, etc. In one example embodiment, the base substrate 100 includes polyimide.

The circuit layer including transistors TR1, TR2 and TR3 may be formed on the base substrate 100. The circuit layer may include wiring layers and insulating layers that form a thin film transistor array (TFT-Array).

The circuit layer may further include a buffer layer 105 on a top surface of the base substrate 100. The buffer layer 105 may block penetration of moisture through the base substrate 100 and may also block diffusion of impurities between the base substrate 100 and structures formed thereon.

The buffer layer 105 may include an inorganic insulating material such as silicon oxide, silicon nitride or silicon oxynitride. The buffer layer 105 may include one of the aforementioned materials, or a combination thereof. In some embodiments, the buffer layer 105 may have a stacked structure including a silicon oxide layer and a silicon nitride layer.

The buffer layer 105 may be formed by a deposition process such as a chemical vapor deposition (CVD) process, a sputtering process, an atomic layer deposition (ALD) process, or the like.

The transistors TR1, TR2 and TR3 may be disposed on the buffer layer 105. The first transistor TR1, the second transistor TR2 and the third transistor TR3 may be electrically connected to corresponding first light-emitting device ED1, second light-emitting device ED2 and third light-emitting device ED3, respectively.

The transistors TR1, TR2 and TR3 may each include an active layer 110, a gate insulation layer 120, and a gate electrode 130. The circuit layer may include connection electrodes 150 and 160 connected to the active layer 110.

The active layer 110 may be disposed on the buffer layer 105, and may be patterned by a photo-lithography process to be repeatedly and regularly arranged for each pixel. The active layer 110 may include a silicon compound such as one or more of amorphous silicon and polysilicon. Regions of the active layer 110 may include p-type dopants, n-type dopants or both. The active layer 110 may include a source region, a drain region, and a channel region.

The active layer 110 may include an oxide semiconductor, such as indium gallium zinc oxide (IGZO), zinc tin oxide (ZTO), or ITZO.

The gate insulation layer 120 may be formed on the active layer 110, and the gate electrode 130 may be stacked on the gate insulation layer 120. As illustrated in FIG. 7, the gate insulation layer 120 may be patterned to partially cover each active layer 110. Alternatively, the gate insulation layer 120 may extend continuously over multiple pixels or light-emitting regions, and may be provided as a common layer for the first, second and third transistors TR1, TR2 and TR3.

The gate electrode 130 may overlap the channel region of the active layer 110 in a thickness direction.

The gate insulation layer 120 may be formed by the above-described deposition process to include an inorganic insulating material such as silicon oxide, silicon nitride, silicon oxynitride, or the like. In some implementations, the gate insulation layer 120 having a patterned shape may be formed as illustrated in FIG. 7 by a photo-lithography process in which the gate electrode 130 may be used as an etching mask.

In some implementations, the gate electrode 130 and the gate insulation layer 120 may be used as an ion-implantation mask to form the source region and the drain region in the active layer 110.

An insulating interlayer 140 may be formed on the active layer 110 to cover the gate electrode 130 and the gate insulation layer 120. Connection electrodes 150 and 160 may be in contact with or electrically connected to the active layer 110. The connection electrodes 150 and 160 may be formed on the insulating interlayer 140.

The insulating interlayer 140 may be formed by the above-described deposition process to include an inorganic insulating material such as silicon oxide, silicon nitride, silicon oxynitride, or the like. The insulating interlayer 140 may be formed in a single-layered structure or a multi-layered structure including different materials.

In some implementations, the active layer 110 includes an oxide semiconductor, hydrogen (H) in the insulating interlayer 140 that may be diffused or transferred to the active layer 110 through a heat-treatment process when forming the insulating interlayer 140. Accordingly, the source region and the drain region may be formed at edge portions of the active layer 110.

The connection electrodes 150 and 160 may penetrate the insulating interlayer 140 and may be connected to the active layer 110. In implementations having the gate insulation layer 120 continuously formed commonly in a plurality of the pixel regions, the connection electrodes 150 and 160 may also penetrate the gate insulation layer 120.

The connection electrodes 150 and 160 may include a source electrode 150 connected to or in contact with the source region of the active layer 110 and a drain electrode 160 connected to or in contact with the drain region of the active layer 110.

Contact holes may be formed by partially etching the insulating interlayer 140. For example, the contact holes exposing the source region and the drain region may be formed by partially etching the insulating interlayer 140. A metal layer may be formed over the insulating interlayer 140 sufficiently filling the contact holes to make conductive contact with the source region and drain region. Then the metal layer may be etched to form the source electrode 150 and the drain electrode 160.

The gate electrode 130 and the connection electrodes 150 and 160 may include a metal such as Ag, Mg, Al, W, Cu, Ni, Cr, Mo, Ti, Pt, Ta, Nd, Sc, or the like, an alloy thereof, or a nitride thereof. The gate electrode 130 and the connection electrodes 150 and 160 may be formed by the above-mentioned deposition process and the photo-lithography process.

A planarization layer 170 covering the connection electrodes 150 and 160 may be formed on the insulating interlayer 140. The planarization layer 170 may accommodate a via structure electrically connecting the pixel electrode 180 and the drain electrode 160.

In some embodiments, the planarization layer 170 may include an organic material such as polyimide, an epoxy resin, an acrylic resin, polyester, a siloxane resin, a benzocyclobutene (BCB), or the like. The planarization layer 170 may be formed by the above-described deposition process or a spin coating process.

The circuit layer may further include scan lines and data lines described with reference to FIG. 6. The scan lines may be connected to the gate electrode 130, and the data lines may be connected to the source electrode 150.

The light-emitting devices ED1, ED2 and ED3 including a pixel electrode 180, a light-emitting portion and a counter electrode 190 may be disposed on the circuit layer.

The pixel electrode 180 may be formed for each pixel to electrically connect to the pixel to its corresponding transistor. In an embodiment, the pixel electrode 180 may be formed on the planarization layer 170 to be electrically connected to the drain electrode 160.

For example, the planarization layer 170 may be etched to form a via hole to a top surface of the drain electrode 160. A conductive layer including a metal material or a transparent conductive oxide may be formed on a top surface of the planarization layer sufficiently filling the via hole to make conductive contact with the drain electrode 160., t=The conductive layer may then be etched to form the pixel electrode 180.

The pixel electrode 180 may serve as an anode and may include a high work function conductive material that promotes hole injection. The pixel electrode 180 may be formed as a transmissive electrode. The pixel electrode 180 may include a transparent conductive oxide such as indium tin oxide (ITO), indium zinc oxide (IZO), zinc oxide (ZnO), indium tin oxide (ITZO), or the like.

The pixel electrode 180 may be formed as a translucent electrode or a reflective electrode. The pixel electrode 180 may include a metal selected from Ag, Mg, Cu, Al, Pt, Pd, Au, Ni, Nd, Ir, Cr, Li, Ca, LiF, Mo, Ti, W, In, Sn and Zn, or an alloy of two or more therefrom.

The pixel electrode 180 may have a single-layered structure or a multi-layered structure. For example, the pixel electrode 180 may have a triple-layered structure of ITO/Ag/ITO.

The pixel defining layer PDL may be formed on the planarization layer 170 and may be formed on a portion of the top surface of the pixel electrode 180. Pixel regions PX1, PX2 and PX3 may be defined by a sidewall of the pixel defining layer PDL. A blue light-emitting region (e.g., a first pixel region PX1), a green light-emitting region (e.g., a second pixel region PX2), and a red light-emitting region (e.g., a third pixel region PX3) may be separated/defined by the pixel defining layer PDL. The first light-emitting device ED1, the second light-emitting device ED2 and the third light-emitting device ED3 may correspond to a blue light-emitting device, a green light-emitting device and a red light-emitting device, respectively.

In some embodiments, all of the light-emitting devices ED1, ED2 and ED3 may be white light-emitting devices or blue light-emitting devices.

The light-emitting portion may be disposed in each light-emitting region formed by the pixel defining layer PDL. According to embodiments, the light-emitting portion may include an emission layer EML including an organic light-emitting material. For example and without limitation, the emission layer EML may include a fluorescent host and/or a phosphorescent host, and may further include a fluorescent dopant, a phosphorescent dopant and/or a thermally activated delayed fluorescent (TADF) dopant.

The light-emitting portion may be formed by a process such as a vacuum deposition, a spin coating, an inkjet printing, a laser printing, a casting, a laser thermal transfer, or the like.

A counter electrode 190 may be disposed on a top surface of the pixel defining layer PDL and the light-emitting portions. The counter electrode 190 may be a common electrode that is continuous and common between a plurality of the light-emitting regions or the pixels.

The counter electrode 190 may serve as an electron injection electrode or a cathode. The counter electrode 190 may include a metal, an alloy, an electrically conductive compound, or the like, having a low work function.

For example, the counter electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like, used alone or in combination..

The counter electrode 190 may be formed as a transmissive electrode, a translucent electrode, or a reflective electrode. The counter electrode 190 may have a single-layered structure or a multi-layered structure.

The light-emitting portion may further include a hole transport layer HTL and an electron transport layer ETL. According to aspects of the present disclosure, the hole transport layer HTL, the emission layer EML, the electron transport layer ETL and the counter electrode 190 may be sequentially stacked from the top surface of the pixel electrode 180.

For example, the hole transport layer HTL may include an hole transport material such as m-MTDATA (4,4′,4″-[tris(3-methylphenyl)phenylamino] triphenylamine), TDATA (4,4′4″-tris(N, N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

For example, the electron transport layer (ETL) may include an electron transport materials such as an anthracene-based compound, Alq3 (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen)-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

In some embodiments, a hole injection layer may be further disposed between the pixel electrode 180 and the hole transport layer HTL. An electron injection layer may be further disposed between the counter electrode 190 and the electron transport layer ETL.

In some embodiments, the layers included in the above-described light-emitting portion may be patterned in the light-emitting region defined by the pixel defining layer PDL similarly to the emission layer EML illustrated in FIG. 7. Accordingly, the light-emitting portions may be separated from each other in the form of an island in a plurality of the pixels.

In some embodiments, the layers included in the above-described light-emitting portion (e.g., the hole transport layer HTL and the electron transport layer ETL) may be continuous and commonly extend throughout a plurality of the pixel regions and over the top surface of the pixel defining layer PDL.

In some embodiments, an encapsulation layer TFE covering the light-emitting devices ED1, ED2 and ED3 may be disposed on the display panel DP. In an embodiment, the encapsulation layer TFE may be included as a component of the display panel DP.

The encapsulation layer TFE may be disposed over the pixel defining layer PDL and the light-emitting devices ED1, ED2 and ED3 to protect the light-emitting devices ED1, ED2 and ED3 from moisture or oxygen.

The encapsulation layer TFE may include one or more inorganic layers, one or more organic layers or a combination of organic and inorganic layers. An inorganic layers may include silicon nitride (SiNx), silicon oxide (SiOx), indium tin oxide, indium zinc oxide, or any combination thereof An organic layer may include polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)) or any combination thereof.

The encapsulation layer TFE may be formed in a single-layered or a multi-layered structure. In some embodiments, the encapsulation layer TFE may have a stacked structure of a first inorganic layer, an organic layer and a second inorganic layer.

In some embodiments, the display panel DP may further include a color control portion disposed on the light-emitting devices ED1, ED and ED3. The color control portion may include a color filter corresponding to each of the light-emitting devices ED1, ED2 and ED3 or each pixel.

The color filter may selectively transmit a light of a specific wavelength band and may substantially absorb the remaining light. Accordingly, color purity of the display device DD may be increased, and reflection of an external light may be decreased.

The color filter may include a first color filter that transmits a blue light having, e.g., a central wavelength band ranging from 420 nm to 480 nm, a second color filter that transmits a green light having, e.g., a central wavelength band ranging from 500 nm to 580 nm, and a third color filter that transmits a red light having, e.g., a central wavelength band ranging from 600 nm to 670 nm.

In this example the first to third color filters may correspond to the first to third light emitting devices ED1, ED2 and ED3, respectively.

The color control portion may include a color conversion portion including, e.g., quantum dots between the color filter and the light-emitting device. In this case, the display device DD may be provided as a QD-OLED device. For example, a color of emitted light may be adjusted according to a particle size of the quantum dots. The quantum dots may be classified into blue quantum dots, red quantum dots and green quantum dots.

The color conversion portion may include a first color conversion layer, a second color conversion layer and a third color conversion layer. The first color conversion layer, second color conversion layer and third color conversion layer may correspond to and be aligned over the first light-emitting device ED1, the second light-emitting device ED2 and the third light-emitting device ED3, respectively.

According to embodiments, a blue light having a central wavelength band in a range of, e.g., 420 nm to 480 nm may be generated from the light-emitting portion. The first color conversion layer corresponding to the first light-emitting device ED1 may transmit the blue light. In this case, the color conversion layer may not include the quantum dots, and may include a scattering material. The scattering material may include TiO₂, ZnO, Al₂O₃, SiO₂, hollow silica, or the like, present in the material alone or in any combination thereof.

The second color conversion layer corresponding to the second light-emitting device ED2 may convert the blue light into a green light having a central wavelength band in a range of, e.g., 500 nm to 580 nm.

The third color conversion layer corresponding to the third light-emitting device ED3 may convert the blue light into a red light having a central wavelength band in a range of, e.g., 600 nm to 670 nm.

In some embodiments, the first to third light-emitting devices ED1, ED and ED3 may be light-emitting devices having a tandem structure that may emit the same white light. In this case, the first to third light-emitting devices ED1, ED2 and ED3 may be stacked in the third direction with a charge generation layer interposed therebetween for each pixel or the light-emitting region defined by the pixel defining layer PDL.

The lens array structure LA may be stacked on the encapsulation layer TFE. In some embodiments, an adhesive layer may be included between the lens array structure LA and the encapsulation layer TFE.

Lenses LZ included in the lens array structure LA may be disposed in each pixel region PX1, PX2, and PX3 or each pixel PXnm illustrated in FIG. 6. According to an aspect of the present disclosure, the lenses LZ and the pixels PXnm may be matched 1:1 in the structure. For example, one lens LZ may be aligned over each individual pixel PXnm. In another example, one lens LZ may be aligned over each of the first light-emitting devices ED1, each of the second light-emitting devices ED2, and each of the third light-emitting devices ED3.

Accordingly, a light emitted from each of the light-emitting devices ED1, ED2 and ED3 may be incident on each respective lens LZ and emitted through the outermost surface OC of the lens LZ. Thus, as described with reference to FIG. 3, a light scattered from each pixel or the light-emitting device in a lateral direction may be suppressed or reduced, and light-condensing properties may be improved toward a front surface of the display device DD.

Therefore, color purity from each light-emitting device ED1, ED2 and ED3 may be enhanced, and overall light-extraction and luminous properties of the display device DD may also be increased.

The lens array structure LA according to the above-described embodiments may have a single-layered lens structure. Through the above-described refractive index distribution, light-extraction and luminous efficiency of the display device DD may be sufficiently improved by inducing a plurality of light refractions even without arranging multiple lens layers.

In some embodiments, an over-coating layer OCL may be formed on the lens array structure LA. The over-coating layer OCL may serve as a planarization layer covering the lenses LZ. The over-coating layer OCL may include an organic insulating material such as an acrylic resin, an epoxy resin, a siloxane resin, an imide resin, or the like.

A functional layer 200 may be disposed on the over-coating layer OCL. The functional layer 200 may include a sensor device layer such as a touch sensor, an optical layer such as a polarizing plate, a retardation layer and an antireflection layer, or the like.

A window structure WS may be stacked on the functional layer 200. The window structure WS may include a glass substrate, a transparent resin substrate, a hard coating layer, etc., and may provide an outer surface of the display device DD.

In some embodiments, an adhesive layer may be formed between the over-coating layer OCL and the functional layer 200 and/or between the window structure WS and the functional layer 200.

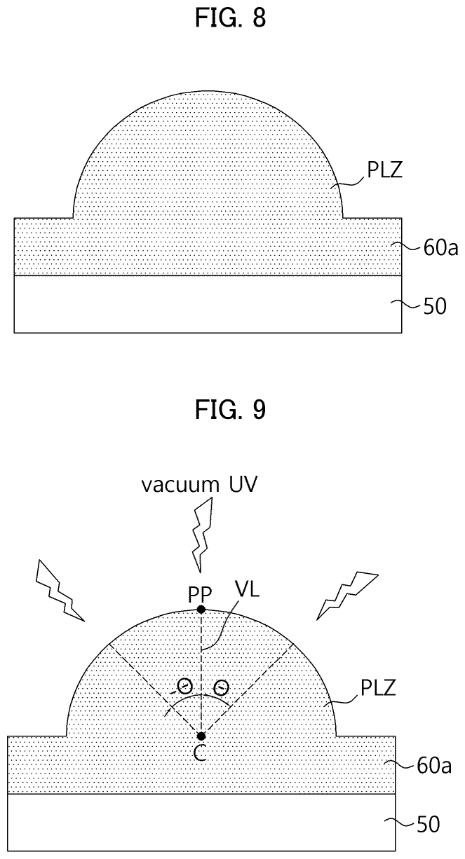

FIGS. 8 and 9 are schematic cross-sectional views illustrating a method of fabricating a lens array structure according to embodiments.

Referring to FIG. 8, a resin material may be applied on the base layer 50 to form a preliminary lens PLZ. For convenience of descriptions, one preliminary lens PLZ is illustrated in FIGS. 8 and 9, but a plurality of the preliminary lenses PLZ may be formed as described with reference to FIG. 1.

According to an aspect of the present disclosure, a resin material containing a silicon-hydrogen (Si—H) bond and/or a nitrogen-hydrogen (N—H) bond may be coated on the base layer 50 through a printing process such as an inkjet printing process. Thereafter, the preliminary lens PLZ may be formed by drying or preliminary-curing. As described above, the resin material may include a siloxane resin and/or a silazane resin.

As illustrated in FIG. 8, a support portion 60a may be formed from the resin material together with the preliminary lens PLZ.

Referring to FIG. 9, vacuum UV (VUV) light may be irradiated onto the preliminary lens PLZ to convert the preliminary lens PLZ into a lens LZ.

According to an aspect of the present disclosure, VUV light having a wavelength of less than 200 nm may be irradiated through an outermost surface of the preliminary lens PLZ using a VUV light source. In some embodiments, the VUV light used to irradiate the preliminary lens may have a wavelength range of 170 to 195 nm, or from 175 nm to 185 nm.

The VUV light irradiation in the selected wavelength range may decompose the Si—H and/or N—H bonds included in the preliminary lens PLZ. Thus, resulting in an increased film density, and refractive index of the material of the preliminary lens PLZ.

A refractive index may be relatively increased at an outer portion while an amount of the VUV light irradiation or transmission decreases from an outer portion to a central portion of the preliminary lens PLZ. Accordingly, as described with reference to FIGS. 2 to 4, the lens LZ having a stepwise or continuous gradient of a refractive index may be formed in a direction from the center toward the outermost surface.

The VUV light irradiation may be performed while rotating the VUV light source along the outermost surface of the preliminary lens PLZ. Accordingly, distribution of the refractive index in the lens LZ may be uniformly adjusted according to a distance from a center C.

For example, as illustrated in FIG. 9, the VUV irradiation may be initiated from a peak point PP (an uppermost point) of the preliminary lens PLZ, and the VUV light source may move from a virtual line VL connecting the center C and the peak point PP to a point corresponding to θ. Thereafter, the VUV light source may rotate clockwise or counterclockwise to a point corresponding to −θ and continuously perform the VUV irradiation.

In some implementations, the VUV irradiation may be appropriately adjusted in consideration of a desired refractive index distribution in an irradiation time range of 10 minutes to 60 minutes, and in a light intensity range of 10 mW/cm² to 300 mW/cm².

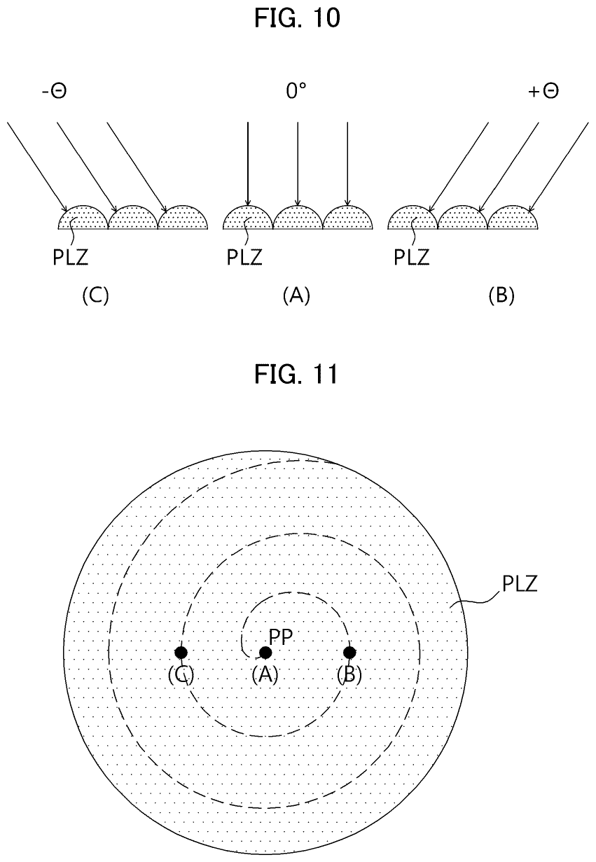

FIGS. 10 and 11 are a cross-sectional view and a plan view, respectively, for describing a light irradiation process of a lens included in a lens array structure.

Referring to FIGS. 10 and 11, the VUV light irradiation described with reference to FIG. 9 may be performed simultaneously with respect to a plurality of the preliminary lenses PLZ. According to some implementations, while the VUV light source performs the light irradiation from the peak point PP designated as (A), the VUV light source may move to a point (B) corresponding to θ with respect to the virtual line VL (see FIG. 9) connecting the center C and the peak point PP along a spiral trajectory. Thereafter, while performing the light irradiation, the VUV light source may move to a point (C) corresponding to −θ with respect to the virtual line VL (see FIG. 9) connecting the center C and the peak point P along the spiral trajectory.

While continuously performing the above-described spiral movement, a substantially uniform irradiation with VUV light may be performed from the peak point PP to a bottom circumference of the preliminary lens PLZ. Accordingly, an inner region of the lens LZ having the same distance from the center C may have a uniform refractive index, and the above-described refractive index gradient distribution may be formed according to the distance from the center C.

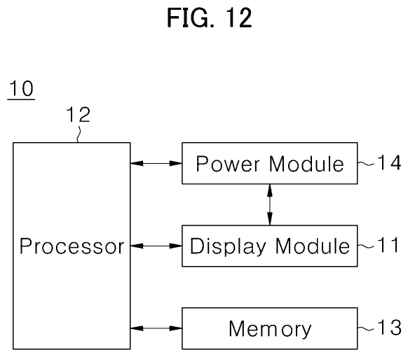

FIG. 12 is a block diagram of an electronic device in accordance with an embodiment.

Referring to FIG. 12, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Instructions for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

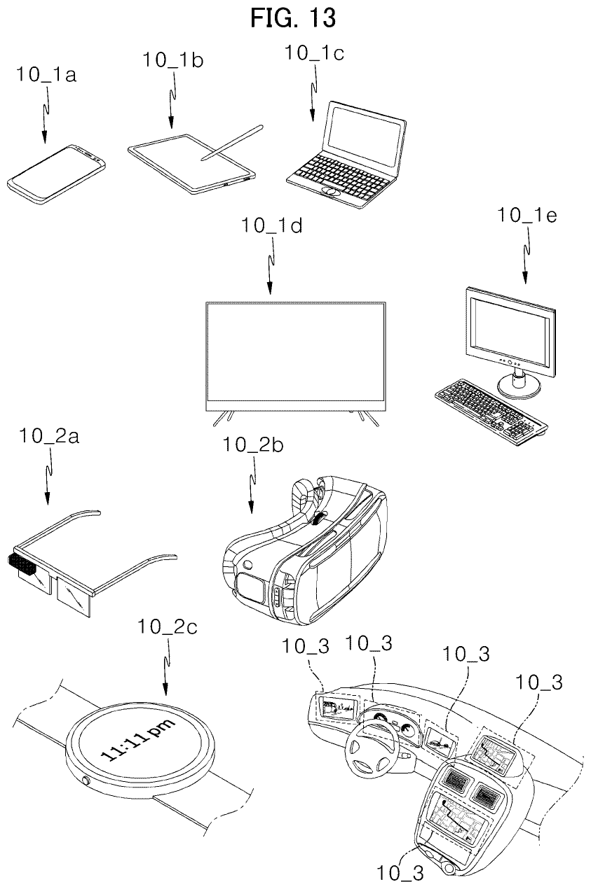

FIG. 13 is a schematic diagram of an electronic device in accordance with various embodiments.

Referring to FIG. 13, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, etc., a room mirror display, and the like. The electronic device may include a virtual reality glass or an augmented reality glass.

What is claimed is:

1. A display device, comprising:
a display panel; and
a lens array structure on the display panel, the lens array structure including a lens having a higher refractive index at an outer portion than at a central portion.

2. The display device according to claim 1, wherein the lens has a refractive index gradient that increases in a direction from a center to an outermost surface.

3. The display device according to claim 2, wherein the lens has a stepwise refractive index gradient.

4. The display device according to claim 3, wherein the lens includes an intermediate portion between the central portion and the outer portion, and a refractive index of the intermediate portion is greater than that of the central portion and less than that of the outer portion.

5. The display device according to claim 4, wherein the intermediate portion includes a first intermediate portion and a second intermediate portion formed from the central portion, and
a refractive index of the first intermediate portion is less than that of the second intermediate portion.

6. The display device according to claim 2, wherein the lens has a continuous refractive index gradient from the center.

7. The display device according to claim 1, wherein the display panel includes a plurality of light-emitting devices, and each lens of the lens array structure is aligned with a corresponding light-emitting device in the plurality of light-emitting devices.

8. The display device according to claim 7, wherein the display panel further includes an encapsulating layer covering the light-emitting devices, and the lens array structure is disposed on the encapsulating layer.

9. The display device according to claim 1, wherein the lens array structure has a single lens layer.

10. The display device according to claim 1, wherein the lens includes a resin material including a silicon-hydrogen (Si—H) bond or a nitrogen-hydrogen (N—H) bond.

11. The display device according to claim 10, wherein the lens includes a siloxane-based resin or a silazane-based resin.

12. An electronic device, comprising:
the display device according to claim 1;
a memory; and
a processor for executing instructions included in the memory to control an operation of the display device.

13. A lens array structure, comprising
a base layer; and
a lens array disposed on the base layer, wherein each lens in the lens array has a higher refractive index at the outer portion than at the center.

14. The lens array structure according to claim 13, wherein each lens has a refractive index gradient that increases stepwise or continuously in a direction from the center toward the outermost surface.

15. The lens array structure according to claim 13, wherein each lens includes poly(methylhydrosiloxane) (PMHS) or perhydropolysilazane (PHPS).

16. A method of fabricating a lens array structure, comprising:
forming a preliminary lens by coating a resin material on a base layer; and
irradiating vacuum ultraviolet (VUV) light through an outermost surface of the preliminary lens to form a lens having a higher refractive index at an outer portion than at a center.

17. The method of claim 16, wherein the resin material includes a silicon-hydrogen (Si—H) bond or a nitrogen-hydrogen (N—H) bond, and
irradiating vacuum ultraviolet light through the outermost surface of the preliminary lens includes decomposing the Si—H bond or the N—H bond at a region of the preliminary lens region through which the vacuum ultraviolet light is transmitted.

18. The method of claim 16, wherein irradiating vacuum ultraviolet light through the outermost surface of the preliminary lens includes forming a refractive index gradient that decreases in a direction from the outermost surface of the preliminary lens to a center of the preliminary lens.

19. The method of claim 16, wherein irradiating vacuum ultraviolet light through the outermost surface of the preliminary lens includes rotating a vacuum ultraviolet light source along the outermost surface of the preliminary lens.

20. The method of claim 19, wherein irradiating the vacuum ultraviolet light through the outermost surface of the preliminary lens includes moving the vacuum ultraviolet light source along a spiral trajectory from a peak point of the preliminary lens.
